(19) United States
(12) Patent Application Publication
(10) Pub. No.: US 2024/0154001 A1
(43) Pub. Date: May 9, 2024

(54) METHOD OF MANUFACTURING NITRIDE SEMICONDUCTOR AND NITRIDE SEMICONDUCTOR THIN FILM PREPARED USING THE SAME

(71) Applicant: Tech University of Korea Industry Academic Cooperation Foundation, Siheung (KR)

(72) Inventors: Ok Hyun Nam, Seoul (KR); Min Ho kim, Incheon (KR); Uiho Choi, Seoul (KR)

(21) Appl. No.: 18/379,107

(22) Filed: Oct. 11, 2023

(30) Foreign Application Priority Data
Nov. 4, 2022 (KR) 10-2022-0146113

(51) Int. Cl. H01L 29/20; H01L 21/02

(52) U.S. Cl. CPC H01L 29/2003; H01L 21/02304; H01L 21/02513; H01L 21/0254; H01L 21/02598

(57) ABSTRACT

A method of manufacturing a nitride semiconductor and a nitride semiconductor thin film prepared using the method are provided. The method includes preparing a substrate, forming a buffer layer by growing a thin film having a three-dimensional (3D) structure on the substrate, and forming a nitride semiconductor layer on the buffer layer.

### CROSS-REFERENCE TO RELATED APPLICATION

This application claims the benefit of Korean Patent Application No. 10-2022-0146113 filed on Nov. 4, 2022, in the Korean Intellectual Property Office, the entire disclosure of which is incorporated herein by reference for all purposes.

### BACKGROUND

### 1. Field of the Invention

One or more embodiments relate to a method of manufacturing a nitride semiconductor and a nitride semiconductor thin film prepared using the method.

### 2. Description of the Related Art

Recently, many studies have been conducted to develop materials with ultra-wide band gaps, as the reliability of devices increases if a band gap increases. Semiconductors that can operate stably in extreme environments including space radiations or high-temperature environments (>400° C.) such as that on Venus are required in many application fields. Aluminum nitride (AlN) is a promising candidate for such application fields because AlN has the highest band gap (6.2 eV) among nitrides and exhibits excellent thermal conductivity and polarization characteristics.

Due to such characteristics of the AlN, the AlN is used as a good material for electronic and optical devices that may operate in extreme environments. An AlN film is mainly grown on a substrate, such as a silicon (Si) substrate, a silicon carbide (SiC) substrate, or a sapphire substrate. Sapphire substrates are generally used as templates for optical devices that operate in the ultraviolet region.

To apply AlN to an electronic device, AlN is generally grown on a Si substrate and a SiC substrate. The Si substrate has advantages of being relatively inexpensive and large. In addition, excellent physical properties of SiC are suitable for high-power and high-frequency devices. However, due to poor thermal conductivity of sapphire, use of sapphire in electronic devices is limited. In addition, research on the growth of AlN on SiC is highly limited because it is difficult to grow high-quality AlN without a crack. In general, an AlN thin film grown on SiC has a critical thickness of about 30 nanometers (nm). However, a critical thickness of about 700 nm requires a special processing technique, and a tensile strain occurs in a thin film due to a difference in a thermal expansion coefficient, which leads to cracks. Therefore, a growth technique that may relieve a strain is significant to grow a thick film.

The above description has been possessed or acquired by the inventor(s) in the course in of conceiving the present disclosure and is not necessarily an art publicly known before the present application is filed.

### SUMMARY

An existing process of growing aluminum nitride (AlN) on silicon carbide (SiC) is highly limited because it is difficult to grow high-quality AlN without a crack due to problems, such as a difference in a thermal expansion coefficient or a difference in a lattice constant. In addition, the existing process of growing the AlN on the SiC may cause problems such as a generation of stress due to multiple interfaces through a structure in which a high temperature and low temperature are repeated as well as an addition of process cost due to additional external processing such as patterning of a substrate.

To solve the problems mentioned above, in a method of manufacturing a nitride semiconductor according to embodiments of the present disclosure, a three-dimensional (3D) buffer layer may be generated by a low-temperature growth process, and a Group III nitride semiconductor (e.g., AlN) thin film (e.g., a film) may be grown on the 3D buffer layer (e.g., a surface), to obtain a high-quality Group III nitride semiconductor. Thus, it is possible to grow a high-quality Group III nitride semiconductor thin film by preventing occurrences of factors (e.g., cracks or stress) that deteriorate the quality, using self-assembled nanovoids, instead of applying an additional mask, and the like, by a 3D buffer layer.

According to an embodiment, a method of manufacturing a nitride semiconductor includes preparing a substrate, forming a buffer layer by growing a thin film having a 3D structure on the substrate, and forming a nitride semiconductor layer on the buffer layer.

According to an embodiment, the substrate may include at least one of silicon, a silicon oxide, a silicon nitride, a silicon carbide, and a combination thereof. According to an embodiment, in the method of manufacturing the nitride semiconductor, the substrate may have a size of about 1 inch or greater.

According to an embodiment, in the method of manufacturing the nitride semiconductor, a vapor deposition process may be used in the forming of the buffer layer. The forming of the buffer layer may include growing the thin film having the 3D structure at a temperature of about 1200° C. or less for about 10 seconds or greater.

According to an embodiment, in the method of manufacturing the nitride semiconductor, a nanovoid may be included at an interface between the buffer layer and the nitride semiconductor layer.

According to an embodiment, in the method of manufacturing the nitride semiconductor, the forming of the nitride semiconductor layer may include vertically growing a nitride semiconductor on the buffer layer at a temperature of about 1000° C. to about 1400° C. for about 10 seconds or greater.

According to an embodiment, in the method of manufacturing the nitride semiconductor, the thin film having the 3D structure may include a Group III nitride semiconductor material. The thin film having the 3D structure may include a Group III nitride semiconductor material that is the same as or different from the nitride semiconductor layer.

According to an embodiment, in the method of manufacturing the nitride semiconductor, the thin film having the 3D structure may include a single crystalline Group IIIl nitride semiconductor material.

According to an embodiment, in the method of manufacturing the nitride semiconductor, the buffer layer may have a thickness of about 1 nanometer (run) to about 1 micrometer (μm), and the nitride semiconductor layer may have a thickness of about 10 nm to about 10 μm.

According to an embodiment, a nitride semiconductor thin film may include a substrate, a buffer layer that is a thin film having a 3D structure on the substrate, and a nitride semiconductor layer on the buffer layer.

According to an embodiment, in the nitride semiconductor thin film, the buffer layer may include a nanovoid.

According to an embodiment, the nitride semiconductor layer in the nitride semiconductor thin film may be free of cracks.

According to an embodiment, in the nitride semiconductor thin film, the thin film having the 3D structure may include a Group III nitride semiconductor material. The thin film having the 3D structure may include a Group III nitride semiconductor material that is the same as or different from the nitride semiconductor layer.

According to an embodiment, in the nitride semiconductor thin film, the thin film having the 3D structure may include a single crystalline Group III nitride semiconductor material.

According to an embodiment, in the nitride semiconductor thin film, the buffer layer may have a thickness of about 1 nm to about 1 μm, and the nitride semiconductor layer may have a thickness of about 10 nm to about 10 μm.

According to an embodiment, the nitride semiconductor thin film may be prepared by at least one or a combination of methods according to embodiments of the present disclosure.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 illustrates a process flow of a method of manufacturing a nitride semiconductor according to embodiments;

FIGS. 2A to 2F are field emission scanning electron microscope (FE-SEM) images of aluminum nitride (AlN) buffer layers grown at 850° C. (FIG. 2A), 950° C. (FIG. 2B), 1050° C. (FIG. 2C), 1150° C. (FIG. 2D), 1250° C. (FIG. 2E), and 1350° C. (FIG. 2F), according to embodiments;

FIG. 3 illustrates full widths at half maximum (FWHMs) of X-ray rocking curves (XRCs) of (002) and (102) reflections of an AlN buffer layer as a function of a growth temperature, according to embodiments;

FIGS. 4A to 4E are FE-SEM images of AlN layers grown on low temperature (LT) buffer layers at a growth temperature of 1050° C. for 200 seconds (FIG. 4A), 400 seconds (FIG. 4B), 600 seconds (FIG. 4C), 800 seconds (FIG. 4D) and an AlN layer (FIG. 4E) grown without a buffer layer, according to embodiments;

FIGS. 5A and 5B illustrate Raman spectra (FIG. 5A) of an AlN layer on an LT buffer layer (1050° C.) and an AlN layer that is not overgrown during a period in which another buffer layer is used, and a Raman shift (FIG. 5B) corresponding to an E₂ high peak and residual stress according to embodiments;

FIGS. 6A and 6B illustrate XRCs of (002) (FIG. 6A) and (102) (FIG. 6B) for an AlN layer with a thickness of 2.5 micrometers (μm) grown on an LT buffer layer (1050° C.) for 2400 seconds, according to embodiments; and

FIG. 7 is a bright field cross-sectional transmission electron microscope (TEM) image of an AlN layer with a thickness of 2.5 μm grown on an LT buffer layer (1050° C.) for 2400 seconds, based on an enlarged image of a region close to a buffer layer defined by a rectangular box using g=11-20, according to embodiments.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. Each of these terms is not used to define an essence, order or sequence of a corresponding component but used merely to distinguish the corresponding component from other component(s). It is to be understood that if a component is described as being “connected”, “coupled” or “joined” to another component, the former may be directly “connected”, “coupled”, and “joined” to the latter or “connected”, “coupled”, and “joined” to the latter via another component.

As used herein, “A or B”, “at least one of A and B”. “at least one of A or B”, “A, B or C”. “at least one of A, B and C”, and “at least one of A, B, or C”, each of which may include any one of the items listed together in the corresponding one of the phrases, or all possible combinations thereof.

Components included in an embodiment and components having a common function will be described using the same names in other embodiments. Unless otherwise mentioned, the descriptions on the embodiments may be applicable to the following embodiments and thus, duplicated descriptions will be omitted for conciseness.

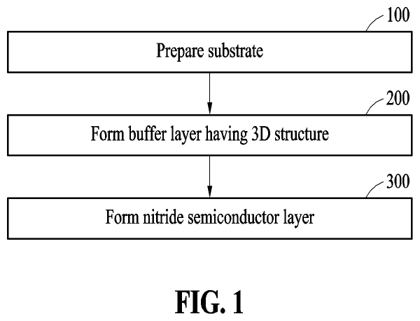

FIG. 1 illustrates a process flow of a method of manufacturing a nitride semiconductor according to embodiments. Referring to FIG. 1, the method may include step 100 of preparing a substrate, step 200 of forming a buffer layer having a three-dimensional (3D) structure, and step 300 of forming a nitride semiconductor layer.

According to an embodiment, step 100 of preparing the substrate may be selected according to use of nitride semiconductor crystals that may be grown and applied. According to an embodiment, the substrate may include at least one of sapphire (Al₂O₃), silicon (Si), a silicon oxide (SiO₂), a silicon nitride, a silicon carbide (SiC), GaN, GaAs, AlN, and a combination thereof, but is not limited thereto. In some examples, the substrate may be a substrate having a surface on which a Group III nitride semiconductor crystal having good crystallinity may be epitaxially grown and laminated. In some examples, the substrate may be selected from a sapphire substrate, a SiC substrate, and a silicon substrate. According to an embodiment, the substrate may have a size of about 1 inch or greater; about 2 inches or greater; and about 6 inches or greater, or may have a wafer size of about 12 inches or greater. According to an embodiment, the substrate may be cleaned with plasma or high-temperature gas (e.g., a temperature of about 900° C. or greater).

According to an embodiment, in step 200 of forming the buffer layer having the 3D structure, the buffer layer may be formed by growing a thin film having a 3D structure on a substrate (e.g., a surface). According to an embodiment, a vapor deposition such as a physical vapor deposition or a chemical vapor deposition may be used to form the buffer layer. For example, a vapor deposition process, such as sputtering, vacuum evaporation, atomic layer deposition (ALD), thermal evaporation, metal organic chemical vapor deposition (MOCVD), molecular beam epitaxy (MBE), hydride vapor phase epitaxy (HVPE), and the like, may be used to form the buffer layer, however, embodiments are not limited thereto. In some examples, a Group III nitride semiconductor may be formed by reacting a gas containing a Group V element (e.g., nitrogen) and a Group III element material through a plasma activation. In some examples, MOCVD may be used.

According to an embodiment, in step 200 of forming the buffer layer having the 3D structure, a thin film having a 3D structure may be grown at a growth (or deposition) temperature of about 1300° C. or less; about 1250° C. or less; about 1200° C. or less; about 1150° C. or less; about 1100° C. or less; about 1050° C. or less; about 950° C. or less; about 900° C. or less; about 800° C. or less; about 700° C. or less; about 600° C. or less; about 500° C. or less; about 450° C. or less; about 400° C. or greater; about 450° C. or greater, about 500° C. or greater; about 600° C. or greater; about 700° C. or greater; about 800° C. or greater; about 900° C. or greater; about 950° C. or greater; 1000° C. or greater; or 1050° C. or greater for about 10 seconds (s) or greater; about 100 s or greater; about 200 s or greater; about 300 s or greater; about 500 s or greater; about 800 s or greater: about 1000 s or greater. In some examples, desirably, the growth temperature may be about 1150° C. or less; about 1100° C. or less; or 1050° C. or less. In some examples, the growth temperature may be in a range of about 450° C. to about 1150° C.; about 450° C. to about 1100° C.; about 450° C. to about 1050° C.; or about 450° C. to about 1000° C.

According to an embodiment, step 200 of forming the buffer layer having the 3D structure may be performed at a high pressure or low pressure. In some examples, step 200 may be performed at a pressure of about 10 hectopascals (hPa) to about 500 hPa. In some examples, step 200 may be performed at a pressure of about 10 hPa or less; about 5 hPa or less; about 1 hPa or less; about 0.1 hPa or less; or about 0.01 hPa or less; or a pressure of about 0.001 hPa to about 1e-7 hPa. In some examples, by applying the temperatures, time, and/or pressures described above, a buffer layer that has a surface with a 3D structure and that reduces or does not include macroscopic defects such as polycrystallinity may be formed. Vertical growth of a nitride semiconductor layer which is to be performed in a next step may be induced, and self-assembled voids (e.g., nanovoids) may be formed within a layer (e.g., an interface or a region close to the interface).

According to an embodiment, in step 200 of forming the buffer layer having the 3D structure, a molar ratio of a Group V precursor to a Group III precursor may be about 100 or greater; about 200 or greater; about 500 or greater; about 1000 or greater; about 1500 or greater, about 2000 or greater; or in a range of about 200 to about 1000; in a range of about 250 to about 450; in a range of about 250 to about 350; or about 300. In some examples, a high-quality nitride semiconductor layer may be formed within the above-described range.

According to an embodiment, in step 200 of forming the buffer layer having the 3D structure, a flow rate of each of the Group V precursor and the Group III precursor may be about 50 standard cubic centimeters per minute (sccm) or greater, about 100 sccm or greater; and in a range of about 150 sccm to about 250 sccm.

According to an embodiment, the thin film having the 3D structure may include a single crystalline Group III nitride semiconductor structure. For example, the thin film having the 3D structure may include a polycrystallinity of about 5% or less, a polycrystallinity of about 2% or less, a polycrystallinity of about 1% or less, a polycrystallinity of about 0.5% or less, or a polycrystallinity of about 0%. In some examples, the thin film may not include a polycrystallinity. In some examples, the quality of a next grown nitride semiconductor layer may be increased by lowering macroscopic defects such as a polycrystallinity.

According to an embodiment, the buffer layer may have a thickness of about 1 nanometer (nm) to about 1 micrometer (μm); about 2 nm to about 900 nm; about 5 nm to about 600 nm; about 5 nm to about 300 nm; about 10 nm to about 100 nm; or about 5 nm to about 50 nm. A high-quality Group III nitride semiconductor may be formed within the thickness range described above.

According to an embodiment, the buffer layer may include a nanovoid, and the nanovoid may have a size of about 1 nm to about 1 μm. In some examples, a high-quality Group III nitride semiconductor may be formed within the thickness range described above.

According to an embodiment, the buffer layer may include a Group III nitride semiconductor material, and may include at least one Group III element selected from Al, Ga, In, and a combination thereof. For example, the buffer layer may further include elements such as Ge, Si, Mg, Ca, Zn, Be, P, Sb, and As, if necessary. For example, the buffer layer may include AlN, GaAlN, GaN, GaNP, GaNAs, GaNSb, AlGaN, InGaN, BAlGaN, GaAlNP, GaAlNAs, InAlGaN, GaAlNSb, GaInNP, GaInNAs, and GaInNSb, but is not limited thereto. In some examples, the buffer layer may be AlN. In some examples, the buffer layer may include a Group III nitride semiconductor material that is the same as or different from a nitride semiconductor layer that is to be formed in a next step. Desirably, the buffer layer may include the same Group III nitride semiconductor material as the nitride semiconductor layer, and a nitride semiconductor layer may be formed through a re-growth step after the buffer layer is formed.

According to an embodiment, step 300 of forming the nitride semiconductor layer may be performed to grow the nitride semiconductor layer on the buffer layer, and may be performed as a continuous step by changing the temperature (e.g., higher temperature) after the forming of the buffer layer.

According to an embodiment, in step 300 of forming the nitride semiconductor layer, a vapor deposition such as a physical vapor deposition or a chemical vapor deposition may be used. For example, a vapor deposition process, such as sputtering, vacuum evaporation, atomic layer deposition (ALD), thermal evaporation, metal organic chemical vapor deposition (MOCVD), molecular beam epitaxy (MBE), hydride vapor phase epitaxy (HVPE), and the like, may be used to form the nitride semiconductor layer, however, embodiments are not limited thereto. In some examples, a Group III nitride semiconductor may be formed by reacting a gas containing a Group V element and a Group III element material through a plasma activation. In some examples, MOCVD may be used. In some examples, the same vapor deposition process as a process used to form the buffer layer may be used.

According to an embodiment, in step 300 of forming the nitride semiconductor layer, a nitride semiconductor may be grown on the buffer layer at a temperature of about 1000° C. or greater; about 1100° C. or greater; about 1200° C. or greater; or a temperature of about 1200° C. to about 1400° C. for about 10 s or greater; about 100 s or greater; about 200 s or greater; about 300 s or greater, about 500 s or greater, about 800 s or greater, or about 1000 s or greater. According to an embodiment, step 300 of forming the nitride semiconductor layer may be performed at a high pressure or a low pressure. In some examples, step 300 may be performed at a pressure of about 10 hPa to 500 hPa. In some examples, step 300 may be performed at a pressure of about 10 hPa or less; about 5 hPa or less; about 1 hPa or less; about 0.1 hPa or less; or about 0.01 hPa or less; or in a range of about 0.001 hPa to about 1e-7 hPa. In some examples, step 300 may be performed at a pressure of about 50 hPa to about 500 hPa. In some examples, the nitride semiconductor layer may be grown at a temperature higher than that of the buffer layer. In some examples, nanovoids may be formed in the nitride semiconductor layer during growth. For example, self-assembled nanovoids may be formed at an interface between the buffer layer and the nitride semiconductor layer or in a region close to the interface and may promote vertical growth. In some examples, a ratio (%) of horizontal growth to vertical growth in the nitride semiconductor layer may be less than 50; in a range of greater than 50 to 1:99; in a range of 30:70 to 5:95; or in a range of 20:80 to 5:95. In some examples, nanovoids may relieve a strain of the nitride semiconductor layer and also significantly reduce a formation of defects. As a result, by introducing the buffer layer having the 3D structure on a substrate (e.g., SiC), growth of a low-defect and high-quality nitride semiconductor (AlN) thin film may be promoted. In some examples, the nitride semiconductor layer may be free of cracks.

According to an embodiment, in step 300 of forming the nitride semiconductor layer, a molar ratio of a Group V precursor to a Group III precursor may be about 100 or greater, about 200 or greater; about 500 or greater; about 1000 or greater; about 1500 or greater; about 2000 or greater; or in a range of about 200 to about 1000; in a range of about 250 to about 450; in a range of about 250 to about 350; or about 300. In some examples, a high-quality nitride semiconductor layer may be formed within the above-described range.

According to an embodiment, in step 300 of forming the nitride semiconductor layer, a flow rate of each of the Group V precursor and the Group III precursor may be about 50 sccm or greater; about 100 sccm or greater; or in a range of about 150 sccm to about 250 sccm.

According to an embodiment, the thickness of the nitride semiconductor layer may be greater than that of the buffer layer and may be, for example, in a range of about 10 nm to about 10 μm.

According to an embodiment, a nitride semiconductor material (e.g., a thin film, a film, or a sheet) or a nitride semiconductor device may be provided by the method of the present disclosure. According to an embodiment, the nitride semiconductor material (e.g., a thin film, a film, or a sheet) or the nitride semiconductor device may include a substrate, a buffer layer that is a thin film having a 3D structure on a substrate, and a nitride semiconductor layer on the buffer layer. The substrate, the buffer layer, and the nitride semiconductor layer are the same as those described in the method according to the present disclosure. According to an embodiment, the nitride semiconductor material (e.g., a thin film, a film, or a sheet) or the nitride semiconductor device may include a high-quality nitride semiconductor layer uniformly formed with fewer defects or without cracks. According to an embodiment, the nitride semiconductor material (e.g., a thin film, a film, or a sheet) may be used as a template for semiconductor device applications.

Hereinafter, the present disclosure will be described in detail with reference to examples. However, the following examples are only for illustrating the present disclosure, and the present disclosure is not limited to the following examples.

### EXAMPLES

An AlN thin film was grown using an HT-MOCVD (Top Engineering, PHAETHON 100U) reactor. Trimethylaluminum (TMA) was used as a Group III precursor, and ammonia (NH₃, 99.999%) was used as a Group V precursor. Hydrogen (H₂) was used as a carrier gas. During a deposition of AlN, the pressure was 67 hPa, the flow rate of TMA was 170 sccm, and the ratio of Groups V/Ill was 300. A substrate was a Si face of the on-axis semi-insulating 4H-SiC (0001) (Cree Inc (Durham. NC, USA)). Prior to the deposition of the AlN layer, a SiC substrate was thermally cleaned in a high-temperature H₂ atmosphere. To obtain a buffer layer having a 3D structure, the growth temperature of the buffer layer was changed from 850° C. to 1350° C. while maintaining the growth time at 600 s.

The growth speed of the buffer layer was gradually reduced from 1 nm/sec to 0.3 nm/sec as the temperature increases. Subsequently, an AlN thin film as a main layer was grown on a buffer layer (hereinafter, referred to as an “LT buffer”) having a 3D structure for 2400 s. The total thickness of the AlN thin film with the LT buffer is about 2.5 μm.

The strain of the AlN film was analyzed through a Raman spectroscopy (Nost, FEX, laser wavelength: 532 nm), and full widths at half maximum (FWHMs) of X-ray rocking curves (XRCs) were measured according to symmetric (002) and asymmetric (102) diffraction conditions, using a high-resolution X-ray diffraction (HR-XRD) (with a triple-axis module and rocking curve detector).

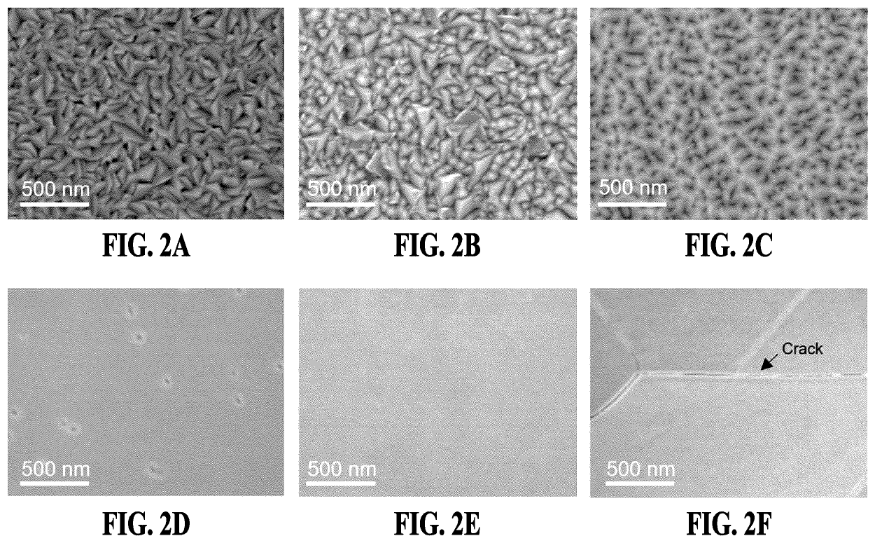

FIGS. 2A to 2F illustrate surface behaviors of buffer layers according to a growth temperature of an AlN buffer layer having a 3D structure and are field emission scanning electron microscope (FE-SEM) images of AlN buffer layers according to the growth temperature.

FIGS. 2A to 2F illustrate layers grown at 850° C., 950° C., 1050° C., 1150° C., 1250° C., and 1350° C., respectively, with a deposition time of 600 s. The thickness of the AlN buffer gradually decreases from 600 nm to 200 nm as the temperature increases. As the temperature increases, a growth behavior at a surface of a layer changes from island growth to layer-by-layer growth. A layer exhibits a 3D structure at a growth temperature between 850° C. and 1050° C. However, when the growth temperature exceeds 1150° C., the layer is grown in a two-dimensional (2D) mode. In addition, a layer grown at 1350° C. has cracks, and lateral growth is promoted as the growth temperature rises, which may lead to a significant strain. In FIGS. 2A to 2C, a buffer layer with a 3D shape may be confirmed.

In FIGS. 2A and 2B, shapes in various directions in which crystals are tilted may be confirmed. This is because Al atoms are randomly attached at each step without aligned stacks due to LT growth. Such a surface exhibits a 3D structure, however, macroscopic defects may occur due to multiple interfaces. Accordingly, it may be difficult to completely merge surfaces during regrowth, which is concerned in buffer applications. In addition, polycrystals may have a negative influence on device performance.

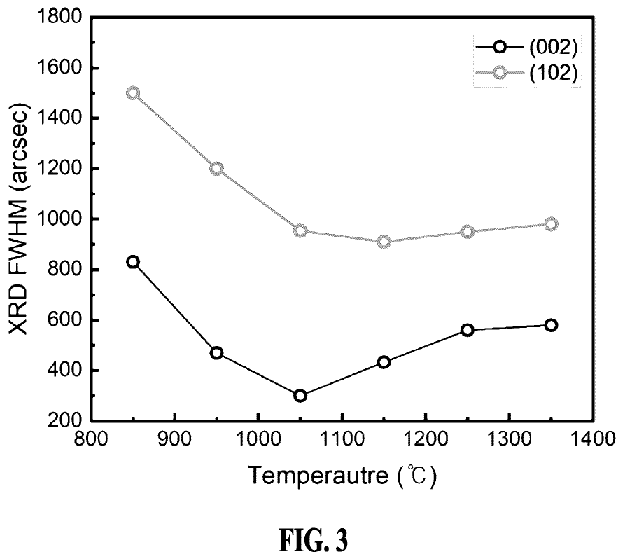

FIG. 3 illustrates FWHMs of XRCs showing a change in a crystal quality according to a change in a growth temperature of an AlN buffer layer having a 3D structure. The FWHMs of the XRCs of FIG. 3 show the change in the crystal quality according to the temperature in terms of (002) and (102) reflections. High FWHM values can be observed at growth temperatures of 850° C. and 950° C. indicating a large number of tilted crystals, which indicates that several defects are present due to tilted interfaces. However, FWHMs of samples exposed to temperatures of 1050° C. or greater slightly increase. This is caused by defects occurring due to a propagation of dislocations from a substrate to a surface when the sample is grown directly without a buffer layer. Therefore, a temperature of 1050° C. for forming a layer with a 3D structure may be suitable for buffer growth when a resulting surface shape and crystal quality are considered: macroscopic defects such as polycrystals are not observed at the temperature.

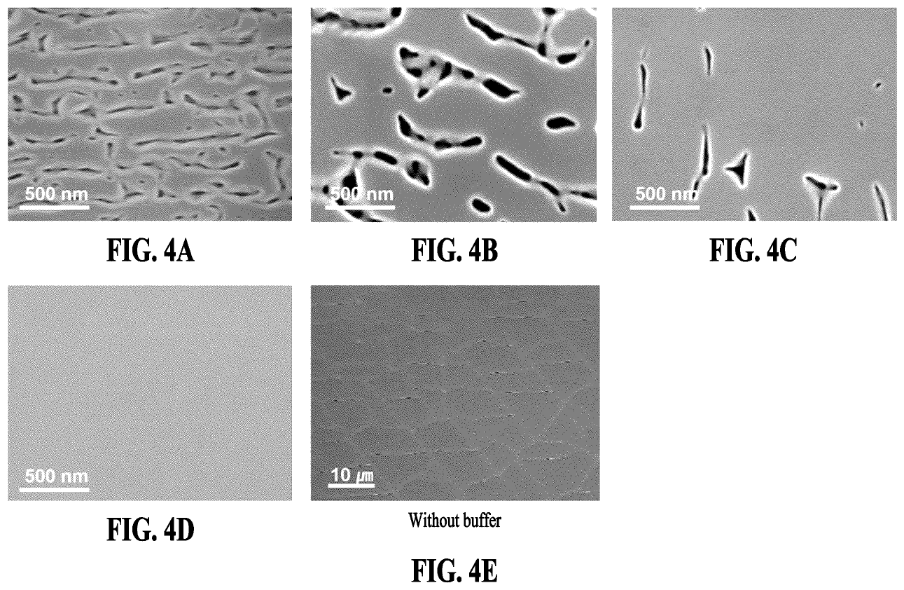

FIGS. 4A to 4D are FE-SEM images of main layers (AlN layers) re-grown on a buffer layer (FIG. 2C) having a 3D structure at a high temperature for 200 s (FIG. 4A), 400 s (FIG. 4B), 600 s (FIG. 4C), and 800 s (FIG. 4D). FIG. 4E illustrates an example of growth on a surface of a substrate without a buffer layer. As the growth time elapses, overgrowth is observed in a sample with a buffer (FIGS. 4A to 4D). Surfaces are merged as the growth time gradually increases, and finally all the surfaces are merged at 800 s (FIG. 4D).

AlN has cohesive energy (2.88 eV) greater than that of GaN (2.20 eV). This is because lateral growth is difficult since diffusion of atoms in AlN is more difficult than in GaN. Accordingly, in response to re-growth (e.g., growth of an AlN layer) in the buffer layer having the 3D structure, a ratio of vertical growth to horizontal growth may be high. Therefore, nanovoids may be formed without a mask or an external process.

FIG. 4E shows that significant cracks occur in an AlN film with a thickness of 1 μm in that is the same as that of FIG. 4D grown without a buffer layer.

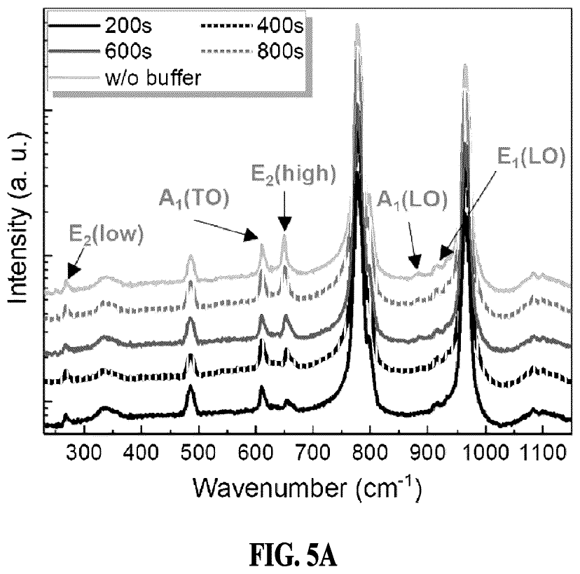

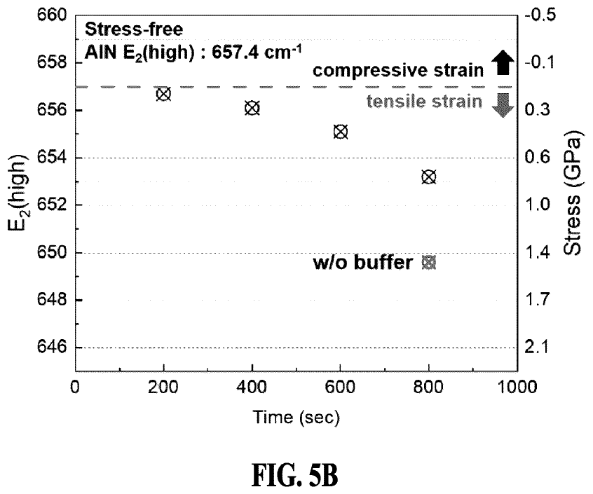

FIGS. 5A and 5B show Raman analysis results according to an increase in a growth time. FIG. 5A shows peaks E₁ (LO, TO). E₂ (high), and A₁ (TO, LO) of AlN corresponding to each peak. FIG. 5B shows a Raman shift of E₂ high peak.

In general, the E₂ high peak is used to measure a strain of a thin film, and a value of the E₂ high peak of stress-free AlN may need to be 657.4 cm⁻¹. A thin film without an LT buffer exhibits the highest tensile strain. If a sample is cooled from the growth temperature to room temperature, AlN crystals may be further contracted than SiC crystals. Due to such biaxial stress, cracks may be formed in the thin film. Thus, the strain may be relaxed due to use of the LT buffer layer, to prevent cracking of the AlN layer.

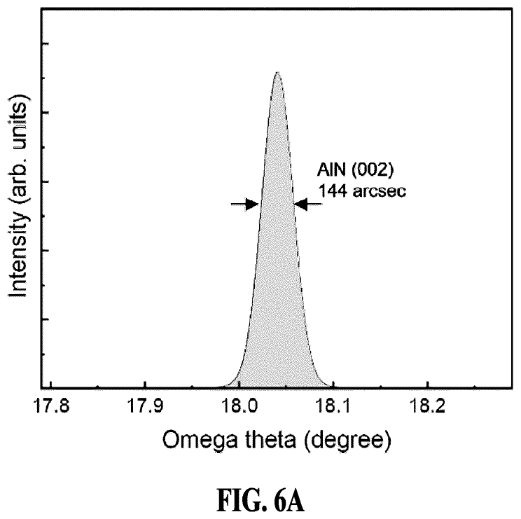

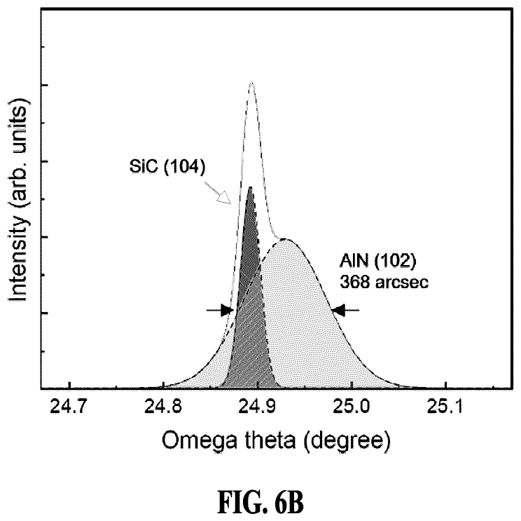

FIGS. 6A and 6B illustrate XRC profiles obtained in a symmetric plane (002) (FIG. 6A) and asymmetric plane (102) (FIG. 6B) of AlN in a SiC film. A sample with an LT buffer (i.e., a buffer layer with a 3D structure) has a thickness of 2.5 μm, and FWHMs of XRCs for (002) and (102) profiles are 144 and 368 arcsec for a film with a buffer layer, respectively, and are 301 and 860 arcsec for film without a buffer layer, respectively. An FWHM of a sample without a buffer layer is twice an FWHM of a sample with a buffer layer. In addition, the threading dislocation densities (TDD) of screw-type dislocations D_{screw} and edge-type dislocations DO in the AlN film was calculated using the following equation:

$${D}_{screw} \frac{{β}_{( 002 )}^{2}}{4 \text{.35} {b}_{screw}^{2}} , {D}_{edge} \frac{{β}_{( 102 )}^{2} - {β}_{( 002 )}^{2}}{4 \text{.35} {b}_{edge}^{2}} . and {D}_{total} = {D}_{screw} + {D}_{edge}$$

Here, b denotes an FWHM of an XRD peak, and β_{screw}(=0.4981 nm) and β_{edge}(=0.3113 nm) denote Burgers vector magnitudes of the screw-type dislocations and edge-type dislocations, respectively. Estimated densities D_{screw} and D_{edge} of an AlN sample were 2.18×10⁷ and 3.65×10⁸ cm⁻², respectively, and the total dislocation density Dₜₒₜₐₗ was 3.87×10⁸ cm⁻².

Due to an insertion of a buffer layer, crystallinity may be greatly increased, a strain of a 3D-structured buffer may be relieved and defects may be reduced. In other words, according to the first reason, voids block defects. A dislocation occurring at an interface between a layer and a substrate is reduced by blocking defects by voids. Second, if a main layer is re-grown with a 3D structure, defects are reduced during lateral growth.

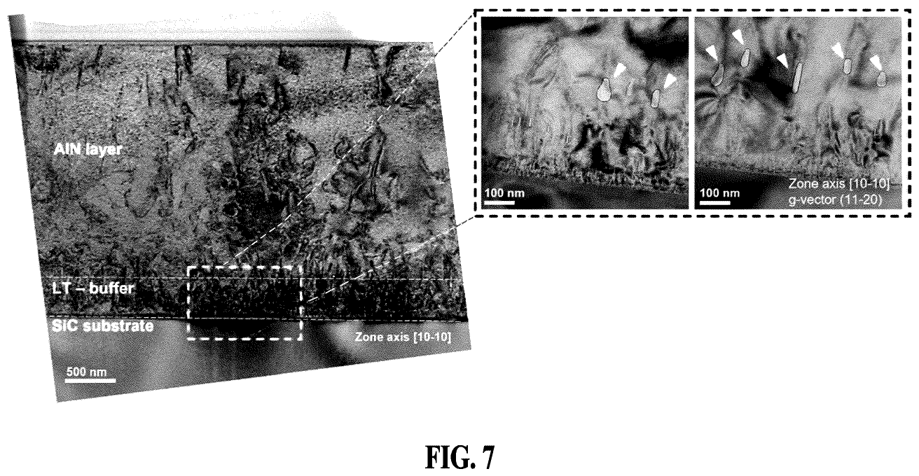

A cross-sectional transmission electron microscopy (TEM) analysis was performed to observe a microstructure of AlN grown on SiC. FIG. 7 is a bright field cross-sectional TEM image of a sample, obtained near a field axis. In FIG. 7, a position ofan AlN layer grown on a SiC substrate by the LT buffer is determined by a growth time and a growth speed, which is indicated by two white dashed lines in FIG. 7. Due to an introduction of an LT buffer, a density of threading dislocations is significantly reduced, which is caused by blocking by voids and bending due to defects by a buffer with a 3D structure described already. An enlarged image of an interface with the buffer layer shows self-assembled nanovoids. The above nanovoids may be used as a special layer to prevent cracking by relieving a strain. In addition, a presence of various types of nanovoids may indicate that a self-assembled AlN thin film is formed as an AlN thin film is vertically grown.

The present disclosure may provide a high-quality AlN film with a thickness of about 2.5 μm grown on a 4H-SiC substrate using a buffer layer with a 3D structure through a vapor deposition (e.g., high-temperature metal organic chemical vapor deposition). For example, in the case of the buffer layer, a form of a 3D structure without polycrystals at a temperature of 850° C. to 1350° C. was selected. Next, a main layer was grown on the selected 3D buffer layer, and self-assembled nanovoids were formed to grow a high-quality and crack-free AlN film. On the contrary, a large number of cracks occur in a sample without a buffer. FWHMs of XRCs for the (002) and (102) planes are 144 and 368 arcsec, respectively. As a result of to an observation using a cross-sectional TEM, the effect of rapidly reducing defects at nanovoids and an interface with the buffer layer may be confirmed.

According to embodiments of the present disclosure, a high-quality Group III semiconductor thin film (e.g., an AlN thin film) may be grown by introducing a buffer layer (i.e., an LT buffer layer) having a 3D structure through a low-temperature process. Thus, it is possible to relieve a strain of a Group III semiconductor thin film and reduce a formation of defects by forming nanovoids in the Group III semiconductor thin film.

According to embodiments of the present disclosure, a Group III nitride thin film (e.g., an AlN thin film) of the present disclosure may be used as a material applicable to a next-generation electronic and optical device field (e.g., a photonic device field).

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A method of manufacturing a nitride semiconductor, the method comprising:
preparing a substrate;
forming a buffer layer by growing a thin film having a three-dimensional (3D) structure on the substrate; and
forming a nitride semiconductor layer on the buffer layer.

2. The method of claim 1, wherein
the substrate comprises at least one selected from a group consisting of silicon, a to silicon oxide, a silicon nitride, a silicon carbide, and a combination thereof, and
the substrate has a size of about 1 inch or greater.

3. The method of claim 1, wherein
in the forming of the buffer layer, a vapor deposition process is used, and
the forming of the buffer layer comprises growing the thin film having the 3D structure at a temperature of about 1200° C. or less for about 10 seconds or greater.

4. The method of claim 1, wherein a nanovoid is included at an interface between the buffer layer and the nitride semiconductor layer or in a region close to the interface.

5. The method of claim 1, wherein the forming of the nitride semiconductor layer comprises vertically growing a nitride semiconductor on the buffer layer at a temperature of about 1000° C. to about 1400° C. for about 10 seconds or greater.

6. The method of claim 1, wherein
the thin film having the 3D structure comprises a Group III nitride semiconductor material, and
the thin film having the 3D structure comprises a Group III nitride semiconductor material that is a same as or different from the nitride semiconductor layer.

7. The method of claim 1, wherein the thin film having the 3D structure comprises a single crystalline Group III nitride semiconductor structure.

8. The method of claim 1, wherein
the buffer layer has a thickness of about 1 nanometer (nm) to about 1 micrometer (μm), and
the nitride semiconductor layer has a thickness of about 10 nm to about 10 μm.

9. A nitride semiconductor thin film comprising:
a substrate;
a buffer layer that is a thin film having a three-dimensional (3D) structure on the substrate; and
a nitride semiconductor layer on the buffer layer.

10. The nitride semiconductor thin film of claim 9, wherein the buffer layer comprises a nanovoid.

11. The nitride semiconductor thin film of claim 9, wherein the nitride semiconductor layer is free of cracks.

12. A nitride semiconductor thin film, wherein the nitride semiconductor thin film is prepared using the method of claim 1.
